(19) United States
(12) Patent Application Publication
(10) Pub. No.: US 2021/0333228 A1
(43) Pub. Date: Oct. 28, 2021

(54) Micro-Four-Point Metrology of Joule-Heating-Induced Modulation of Test Sample Properties

(71) Applicant: KLA CORPORATION, Milpitas, CA (US)

(72) Inventors: Dirch Hjorth Petersen, Herlev (DK); Ole Hansen, Hørsholm (DK); Henrik Hartmann Henrichsen, Copenhagen (DK); Benny Guralnik, Valby (DK)

(21) Appl. No.: 17/066,794

(22) Filed: Oct. 9, 2020

(30) Foreign Application Priority Data
Apr. 24, 2020 (EP) 20171264.3

(51) Int. Cl. G01N 27/14

(52) U.S. Cl. CPC G01N 27/14

(57) ABSTRACT

A method of obtaining a physical property of a test sample, comprising a conductive or semi-conductive material (line/area/volume), by performing electric measurements using a multi-terminal microprobe. Periodic Joule heating within the test sample is induced by passing an ac current across a first pair of probe terminals electrically connected to the test sample, measuring the voltage at one and three times the power supply frequency of the current-conducting terminals across a second pair of probe terminals electrically connected to the test sample, and calculating the temperature-modulated property(ies) of the test sample as a function of the voltage measurements at said frequencies. A value proportional to the Temperature Coefficient of Resistivity (TCR), an Electrical Critical Dimension (ECD), or the true resistivity of the test sample at the ambient experimental temperature by subtracting a measurable TCR offset from the apparent (heating-affected) resistivity of the test sample can be determined.

### CROSS-REFERENCE TO RELATED APPLICATIONS

This application claims priority to the European Patent Application No. 20171264.3 filed Apr. 24, 2020, the disclosure of which is hereby incorporated by reference.

### BACKGROUND OF THE DISCLOSURE

The present invention relates to measuring an electric property of a test sample (device under test) such as a wafer having a number of integrated circuits or memory cells, or any material used in making electrical components where the electrical or geometrical properties need to be measured.

Typically, microscopic multi-terminal probes are used on the test sample by landing a number of cantilevers on the test sample and injecting a current into the test sample followed by a measurement of the voltage between two of the cantilevers.

In this way, it may be verified if the wafer or a particular part of a circuit on the wafer is according to given or desired specifications.

However, as electrical circuit components becomes increasingly smaller, even small test currents may lead to false test values, i.e. the current may lead to heating of the test sample which may result in a measured resistance, which is markedly different (typically larger) than what would be measured at room temperature without the localized heating.

Such thermal effects may also be utilized to measure properties that are temperature dependent, such as the temperature coefficient of resistance. These effects may even be utilized to determine test sample geometries, or the presence or absence of structural and/or compositional defects therein.

### BRIEF SUMMARY OF THE DISCLOSURE

The above object and advantages together with numerous other objects and advantages, which will be evident from the description of the present invention, are according to a first aspect of the present invention obtained by:

A method for measuring a property in response to a temperature modulation of a test sample, said method comprising:

providing said test sample, said test sample being made of an electrically conducting or semiconducting material such as an electrically conducting layer or electrically conducting line or magnetic tunnel junction,

providing at least two terminals such as four terminals, and at least two or four electrically conducting interconnections between said two or four terminals and said electrically conducting or semiconducting material, said two or four electrically conducting interconnections contacting two or four positions at said electrically conducting or semiconducting material,

providing a power source and an electric circuit for generating a current and injecting said current into said electrically conducting or semiconducting material by means of said terminals,

measuring the voltage across a part of said electrically conducting or semiconducting material by means of said terminals,

determining said property as a function of the value of the third harmonic frequency component of said measured voltage.

According to a second aspect of the present invention the above objects and advantages are obtained by:

A method for determining the temperature coefficient of resistance, said method comprising:

providing said test sample, said test sample being made of an electrically conducting or semiconducting material such as an electrically conducting layer or electrically conducting line or magnetic tunnel junction,

providing a set of terminals including at least four terminals, and at least four electrically conducting interconnections between said terminals and said electrically conducting or semiconducting material,

said four electrically conducting interconnections contacting four positions at said electrically conducting or semiconducting material,

providing a power source and an electric circuit for generating a current, injecting a first current into said test sample by means of a first combination of two terminals from said set of terminals,

measuring a first voltage by means of a second combination of two terminals from said set of terminals,

injecting a second current into said test sample by means of a third combination of two terminals from said set of terminals,

measuring a second voltage by means of a fourth combination of two terminals from said set of terminals,

determining the temperature coefficient of resistance or a value proportional to the temperature coefficient of resistance as a function of said first current, said second current, said first voltage, and said second voltage.

According to a third aspect of the present invention the above objects and advantages are obtained by:

A method for determining an electric property of a test sample, said method comprising:

providing said test sample, said test sample being made of an electrically conducting or semiconducting material such as an electrically conducting layer or electrically conducting line or magnetic tunnel junction,

providing at least two terminals such as four terminals, and at least two electrically conducting interconnections between said two terminal and said electrically conducting or semiconducting material,

said two electrically conducting interconnections contacting two positions at said electrically conducting or semiconducting material,

providing a power source and an electric circuit for generating a current and injecting said current into said electrically conducting or semiconducting material by means of said terminals,

measuring the voltage across a part of said electrically conducting or semiconducting material by means of said terminals,

determining the electric resistance of said electrically conducting or semiconducting material at reference temperature as a function of said injected current, said measured voltage, and the value of the third harmonic frequency component of said measured voltage.

Measuring a property in response to a temperature modulation means heating the test sample to a temperature above a background temperature and determining how the heat affects the test sample.

For example, heat may diffuse away from a line in the test sample at various rates depending on the physical shape of the line. In this way, the shape of the test sample may also be inferred. The property may in this way be said to be a temperature-related property.

The property may also be the temperature coefficient of resistance, or a thermoelectric coefficient such as the Peltier coefficient, or the Joule-Thomson coefficient.

A current source is an electrical circuit that provides an electrical current for use in a measurement. The current source may be provided as a voltage source wherein the provided voltage may be converted to a current.

Screening the test sample means performing a measurement and determining if the test sample complies with a manufacturing specification. Such screening is typically performed during manufacturing. If the test sample meets the specification it may be accepted and continue in the production line. If the test sample does not meet the specification it may be rejected (discarded).

An example may be the shape of a part of the test sample that is screened. If the shape does not meet the specification, the functionality of the test sample may be compromised and the test sample may be rejected. The shape may be the cross section of a part of the test sample such as an electrical component or interconnection between components in the test sample. It may also be a notch or indentation present somewhere in the test sample. It may also be line edge roughness, or surface roughness, or other structural defects or compositional impurities, or inhomogeneous electric properties, or voids/cavities, or grain boundaries, or grainsize distributions, etc.

Determining a shape of a test sample refers to determining a shape of a part of the test sample such as an electrical component or interconnection between components in the test sample. The shape may be the cross section, the length section, presence and amount of periodic features such as notches, the thickness of a feature, and so on.

### DESCRIPTION OF THE DRAWINGS

FIG. 1A illustrates a part of test sample or device under test together with a micro multi-terminal probe, consisting of four cantilevers.

FIG. 1B illustrates another part of test sample or device under test, together with the same micro multi-terminal probe.

FIG. 2A shows a graph where the measured voltage is related to fin aspect ratio.

FIGS. 2B-D illustrates three different profiles of a fin 16 having three different fin aspects ratios.

FIG. 3A shows the effect of the six different shapes/geometries on the measured voltage when an electric current is conducted along the line.

FIG. 3B is an example of another property of a test sample that may be measured thermoelectrically.

### DETAILED DESCRIPTION OF THE DISCLOSURE

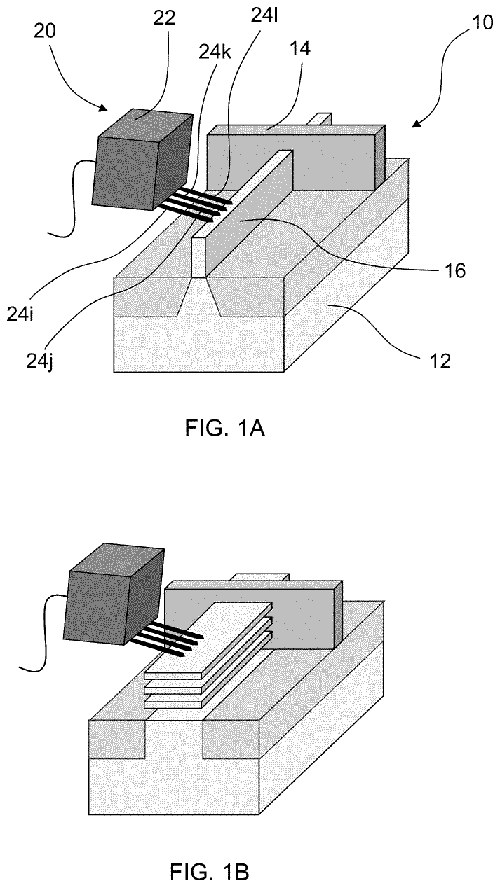

FIG. 1A illustrates a part of test sample or device under test together with a micro multi-terminal probe, consisting of four cantilevers.

The part of the test sample 10 illustrates a fin field-effect transistor (FinFET) on a substrate 12 preferably a silicon substrate. The source and drain terminals are separated by the gate 14.

The measurement in FIG. 1A on the fin of a FinFET is an example and the measurement may be performed on other circuit parts of a test sample, for example a memory cell such as a magnetoresistive random-access memory (MRAM), or another type of transistor, or diode, or a bulk material, or circuit lines between components.

FIG. 1B illustrates another part of test sample or device under test, together with the same micro multi-terminal probe.

The part of the test sample illustrates a gate all-round field-effect transistor (GAAFET) where instead of a fin, three nanosheets are separated by the gate.

A micro multi-terminal probe (specifically, a micro four point probe, M4PP) 20 is shown in contact with the test sample in that the four cantilevers are in contact with the surface of the sample, such that a physical property of the sample may be determined.

The micro four point probe comprises a probe body 22, and four cantilevers including a first cantilever 24i extending from the probe body, a second cantilever 24k, a third cantilever 24j, and a fourth cantilever 24l.

Each cantilever constitutes an electrode for contacting the test sample. The distance (pitch) between any two neighbouring cantilevers may be for example around 0.1 μm, or 1 μm, or 10 μm, or 100 μm.

Each cantilever has a free end opposite the probe body. Each free end constitutes an electrode tip.

The four cantilevers are designated as a first arbitrary pair of electrodes i and j for injecting an electric current (e.g. i for the positive and j for the negative current terminals, respectively), and as a second arbitrary pair of electrodes k and l for measuring the difference in electric potential/voltage between the two electrode tips in the second pair of electrodes (e.g. k for the positive and l for the negative potential terminals, respectively).

A collinear four point probe is a four point probe in which the locations of the electrode terminal contacts with the material under test vary only in one direction, e.g. xᵢ≠xⱼ≠xₖ≠xₗ, while yᵢ=yⱼ=yₖ=yₗ and zᵢ=zⱼ=zₖ=zₗ.

The multi-terminal probe may have more than four cantilevers, for example between four and 20 such as 7, 11 or 12. These cantilevers, in turn, may be subsampled to form arbitrary four-point probes. For example for a probe with seven cantilevers, there are

$$\frac{7 !}{4 ! ( 7 - 4 ) !} = 35$$

unique four-point subprobes. For each subprobe, each of its cantilevers can further be assigned as terminal i, or j, or k, or l, in a mutually-exclusive manner. In any four-point subprobe, there are exactly 4!=24 such unique and mutually-exclusive terminal assignments (configurations). The total number of unique four-point resistance measurements that can be performed by a given probe is the product of the amount of its unique four-point subprobes, and the amount of unique four-point configurations per subprobe, e.g.

$$\frac{7 ! 4 !}{4 ! ( 7 - 4 ) !} = 840$$

in case of a probe with seven terminals.

The measurement of a test sample may involve an arbitrary number of terminals, and correspondingly a possibly arbitrary number of terminal pads, such as two pads for a two terminal sensing or four pads for four terminal sensing or even more pads.

From the terminal, lines or interconnections may extend to the part of the test sample, which is to be tested.

This may be the case if the part to be tested is too small with respect to the probe, prohibiting a direct contact between all the measurement terminals and the part to be tested. This may also be the case if the part to be tested is structurally buried under a functional oxide, another part blocking access to the part to be measured, and so on.

In such a case the interconnections can be said to correspond to the cantilevers/probe electrodes in the probe example (or the lines on the probe that extends from probe pads to the cantilever tips).

In FIG. 1A all four electrode tips are illustrated in contact with a fin 16 such that a physical property of the fin may be determined. This can for example be the resistance, or the geometric profile (in either cross section on along the fin), or surface roughness and/or density of defects, or whether or not the fin meets a specification, or a value proportional to the temperature coefficient of resistance, or a value proportional to the Seebeck coefficient, or a value proportional to the Peltier coefficient, or a value proportional to the thermal conductivity, or a value proportional to the temperature coefficient of resistance, etc.

The measured two-point resistance Rᵢⱼ by e.g. a collinear micro four point probe shown in FIGS. 1A and 1B may be converted to for example the contact resistance R_{C,i} snd R_{C,j} of electrodes i and j as follows. A two-point load resistance R_{i,j} between the first and the second current-injecting electrodes (i and j respectively) corresponds to the in-series (sum) resistance of the sample Rₛₐₘₚₗₑ, plus the lead resistances R_{lead} in each of the wires connecting the voltmeter to the sample, plus the contact resistance R_{C} in the proximity of each electrode-sample interface:

RᵢⱼRₛₐₘₚₗₑ+(R_{lead,i}+R_{lead,j})+(R_{C,i}+R_{C,j})

For an arbitrary number n of two-point resistance measurements using m electrodes, R_{lead} is a column vector containing the lead resistances of them electrodes (known from design and verified experimentally), R_{C} is a column vector with m unknown contact resistances, and R_{L} is a column vector with n measured load resistances for arbitrary current-conducting electrode pairs i and j. Defining M as the n×m design matrix, in which the current-injecting electrodes of each measurement are marked as M(n, i)=M(n,j)=1, while all its other elements are zero, the contact resistances of each electrode R_{C} can be obtained from:

R_{C}=(M^{T}M)⁻¹M_{T}(R_{L}−Rₛₐₘₚₗₑ−MR_{lead})

granted that rank(M)≥m, i.e. that the number of independent observations is equal or greater than the number of unknowns.

Considering a spatially uniform resistivity ρ of the probed material, the transfer resistance R as measured by a micro four point probe, e.g. a collinear four-point probe shown in FIGS. 1A and 1B, can be converted to the resistivity of the material via:

R=ρ/g

where g is a “transfer function”, dependent on the frequency f of the electrical current, the geometry Ω of the probed domain, the distribution of the four point cantilevers in space, the external magnetic field, and so forth. At zero external magnetic fields and at low current frequencies (in the so-called quasi-dc regime), the transfer function g of a collinear four-point probe is given by:

$$g = \frac{2 π}{\vert {x}_{i} - {x}_{k} {\vert}^{- 1} - \vert {x}_{i} - {x}_{l} {\vert}^{- 1} - \vert {x}_{j} - {x}_{k} {\vert}^{- 1} + \vert {x}_{j} - {x}_{l} {\vert}^{- 1}}$$

when the probed domain is bulk halfspace, and:

$$g = \frac{2 π d}{ln ( \vert {x}_{i} - {x}_{k} {\vert}^{- 1} \cdot \vert {x}_{i} - {x}_{l} \vert \cdot \vert {x}_{j} - {x}_{k} \vert \cdot \vert {x}_{j} - {x}_{l} {\vert}^{- 1} )}$$

when the probed domain is a thin sheet of thickness d (where d is much smaller than any inter-electrode distance |xₘ−xₙ|). Other expressions may be derived for more advanced domain geometries, higher frequencies, magnetic fields, non-collinear four-point probes, and so forth.

The sensitivity S of the transfer resistance R (as defined above) to spatial variations in resistivity of the probed domain Ω, can be defined as:

$$S = \frac{g}{{I}^{2}} [ {J}_{i j} ( x , y , z ) \cdot {J}_{k l} ( x , y , z ) ] d Ω$$

where Jᵢⱼ(x,y,z) is the electric current density at (x,y,z) due to current injection at terminals i and j, Jₖₗ(x,y,z) is the electric current density at (x,y,z) due to current injection at terminals k and l, (·) is the dot vector product, and dΩ is an infinitesimal unit of length, or area, or volume of the probed domain. The sensitivity function is a spatial weighting function, such as its integral over the probed domain is unity, i.e.

∫_{Ω}S(r)dr=1

where r is a location vector in space, represented by Cartesian coordinates x in the 1D domain, (x,y) in 2D domain, and (x,y,z) in 3D domain. It can be shown that the sensitivity of transfer resistance to local variations in resistivity within bulk halfspace is given by:

$$S ( x , y , z ) = \frac{d x d y d z}{2 π ( \vert {x}_{i} - {x}_{k} {\vert}^{- 1} - \vert {x}_{i} - {x}_{l} {\vert}^{- 1} - \vert {x}_{j} - {x}_{k} {\vert}^{- 1} + \vert {x}_{j} - {x}_{l} {\vert}^{- 1} )} \times [ ( \frac{x - {x}_{i}}{{r}_{i}^{3}} - \frac{x - {x}_{j}}{{r}_{j}^{3}} ) ( \frac{x - {x}_{k}}{{r}_{k}^{3}} - \frac{x - {x}_{l}}{{r}_{l}^{3}} ) + ( {y}^{2} + {z}^{2} ) ( \frac{1}{{r}_{i}^{3}} - \frac{1}{{r}_{j}^{3}} ) ( \frac{1}{{r}_{k}^{3}} - \frac{1}{{r}_{l}^{3}} ) ] , \\ {r}_{q} = \sqrt{{( x - {x}_{q} )}^{2} + {y}^{2} + {z}^{2}} .$$

and accordingly, for a thin sheet of thickness d is:

$$S ( x , y ) = \frac{d \cdot dxdy}{2 π \cdot ln ( \vert {x}_{i} - {x}_{k} {\vert}^{- 1} \cdot \vert {x}_{i} - {x}_{l} \vert \cdot \vert {x}_{j} - {x}_{k} \vert \cdot \vert {x}_{j} - {x}_{l} {\vert}^{- 1} )} \times [ ( \frac{x - {x}_{i}}{{r}_{i}^{2}} - \frac{x - {x}_{j}}{{r}_{j}^{2}} ) ( \frac{x - {x}_{k}}{{r}_{k}^{2}} - \frac{x - {x}_{l}}{{r}_{l}^{2}} ) + {y}^{2} ( \frac{1}{{r}_{i}^{2}} - \frac{1}{{r}_{j}^{2}} ) ( \frac{1}{{r}_{k}^{2}} - \frac{1}{{r}_{l}^{2}} ) ] , \\ {r}_{q} = \sqrt{{( x - {x}_{q} )}^{2} + {y}^{2}} .$$

Other expressions can be derived in an analogous manner for more advanced domain geometries.

Considering a spatially non-uniform resistivity p of the probed material, the transfer resistance R measured by a micro four point probe is given by:

$$R = \frac{1}{g} {\int }_{Ω} ρ ( r ) S ( r ) d r$$

which for a spatially-uniform ρ(r)=ρ reduces to the former relation R=ρ/g, but extends the treatment to situations where resistivity is spatially variable. In the equation above, the transfer resistance is a spatial integral, where each local resistivity ρ(r) is further weighted by the probe's sensitivity S(r) to resistivity changes at each particular location.

Since resistivity depends on temperature, subjecting a material to thermal gradients leads to spatial variations in its resistivity. The dependence of resistivity ρ, or more generally, of resistance R, on temperature T may be expressed as:

$$\frac{d R}{R} = \frac{d ρ}{ρ} = α dT$$

where α is the temperature coefficient of resistivity (TCR), and d is the derivative operator. For small temperature changes ΔT, a first-order linear approximation may be made:

ρ=ρ₀(1+αΔT)

where ρ₀ is the resistivity at the background temperature, i.e. when no additional heat is applied to the test sample other than that supplied by the “isothermal bath” of the enclosing room. This room temperature or “background temperature” may also be referred to as the reference temperature.

The temperature difference ΔT during a four point probe resistance measurement is proportional to the electric power applied, i.e.

$$Δ T = \frac{{I}^{2}}{κ} β$$

where I is the current, β is a thermal scaling function including the sample's geometry and boundary conditions, and κ is the thermal conductivity of the sample, corresponding to the amount of heat q divided by the temperature gradient ∇T that it is flowing across, i.e. k=−q/∇T. Considering the heating of a bulk halfspace by an electric current conducted from electrode i to j, the thermal scaling function β can be approximated as:

$$β ( x , y , z ) = \frac{1}{2 π} ( \frac{{R}_{c , i}}{\sqrt{{( x - {x}_{i} )}^{2} + {y}^{2} + {z}^{2}}} + \frac{{R}_{c , j}}{\sqrt{{( x - {x}_{j} )}^{2} + {y}^{2} + {z}^{2}}} ) .$$

where R_{C,i} and R_{C,j} refer to contact resistances at the proximity of the tips of the first and the second current conducting electrode. For four point resistance measurements in a thin sheet of thickness d, the function β may be approximated as:

$$β ( {x}^{′} , {y}^{′} ) = \frac{ρ / d}{4 {π}^{3}} {\int }_{- a sinh ( a / {r}_{0} )}^{a sinh ( a / {r}_{0} )} {\int }_{0}^{2 π} \frac{d {σ}^{′} d {τ}^{′}}{{[ {x}^{′} - \frac{a sinh {τ}^{′}}{cosh {τ}^{′} - cos {σ}^{′}} ]}^{2} + {[ {y}^{′} - \frac{sinh {τ}^{′}}{cosh {τ}^{′} - cos {σ}^{′}} ]}^{2}}$$

Where x′ and y′ are transformed coordinates according to:

$$[ \begin{matrix}{x}^{′} \\ {y}^{′} \\ 1\end{matrix} ] = [ \begin{matrix}cos θ & sin θ & 0 \\ - s in θ & cos θ & 0 \\ 0 & 0 & 1\end{matrix} ] [ \begin{matrix}1 & 0 & - {x}_{0} \\ 0 & 1 & - {y}_{0} \\ 0 & 0 & 1\end{matrix} ] [ \begin{matrix}x \\ y \\ 1\end{matrix} ] , \\ θ = a tan 2 ( {y}_{j} - {y}_{i} , {x}_{j} - {x}_{i} ) , {x}_{0} = \frac{{x}_{i} + {x}_{j}}{2} , {y}_{0} = \frac{{y}_{i} + {y}_{j}}{2} .$$

and where r₀ is the electrical contact size of the current-conducting electrodes with the sample.

By combining the presented equations

$$R = \frac{1}{g} {\int }_{Ω} ρ ( r ) S ( r ) d r ,$$

ρ=ρ₀(1+ΔΔT), and ΔT=1²β/κ, we obtain

$$R = \frac{{ρ}_{0}}{g} {\int }_{Ω} [ 1 + \frac{α}{κ} {I}^{2} β ( r ) ] S ( r ) d r$$

which can be further rearranged as:

$$\frac{R}{{R}_{0}} = 1 + \frac{α}{κ} M {I}^{2} , M = {\int }_{Ω} S ( r ) β ( r ) d r$$

where R₀ is the transfer resistance at I→0, and M is a product of the sensitivity function S, with the thermal scaling function β, integrated over the entire sampling domain. If M can be accurately approximated as exemplified above, the magnitude of the electric current I be varied over a range of values, and the ratio R/R₀ be experimentally measured with high precision and accuracy, it is possible to determine the ratio α/κ of the material under test, i.e. the TCR of the probed material further scaled by a constant. Furthermore, due to the fact that in the above relationship, the electrical current is squared, enables the determination of α/κ via several experimental pathways as detailed below.

For an ac current with an amplitude of I₀ and an angular frequency co, the measured voltage may be modelled as:

$$V = I ( t ) R = {R}_{0} [ {I}_{0} sin ( ω t ) + \frac{α}{κ} M {l}_{0}^{3} {sin}^{3} ( ω t ) ]$$

which using trigonometric identities can be expanded to:

$$V = I ( t ) R = {R}_{0} [ {I}_{0} sin ( ω t ) + \frac{3}{4} \frac{α}{κ} M {I}_{0}^{3} sin ( ω t ) - \frac{1}{4} \frac{α}{κ} {MI}_{0}^{3} sin ( 3 ω t ) ]$$

Isolating the amplitudes at the fundamental frequency and at the third harmonic frequency, we have:

$${V}_{ω} = {R}_{0} [ {I}_{0} + \frac{3}{4} \frac{α}{κ} M {I}_{0}^{3} ]$$

$${V}_{3 ω} = - {R}_{0} \frac{1}{4} \frac{α}{κ} M {I}_{0}^{3}$$

Correcting with three times the amplitude at the third harmonic we obtain:

V_{ω}+3V_{3ω}=R₀I₀

Meaning that the resistance at reference temperature is:

$${R}_{0} = \frac{{V}_{ω} + 3 {V}_{3 ω}}{{I}_{0}} = {R}_{ω} + 3 {R}_{3 ω}$$

Thus, the resistance at the reference temperature is a function of the amplitude of the injected current, the voltage amplitude at the fundamental frequency, and three times the voltage amplitude at the third harmonic frequency.

To determine the temperature coefficient of resistance, one may use the above relationships in a direct manner to write:

$$\frac{R}{{R}_{0}} = \frac{{R}_{ω}}{{R}_{ω} + 3 {R}_{3 ω}} = {( 1 + 3 \frac{{R}_{3 ω}}{{R}_{ω}} )}^{- 1} = 1 + \frac{α}{κ} M {I}^{2}$$

Collating all controllable experimental conditions into x:

x=MI²

and the observed first and third harmonic resistances into y:

$$y = {( 1 + 3 \frac{{R}_{3 ω}}{{R}_{ω}} )}^{- 1} - 1$$

it is easy to see that the temperature coefficient of resistance relative to the thermal conductivity, i.e. α/κ corresponds to the linear slope of y vs. x, which should further intersect the origin. Given a known thermal conductivity, the absolute value of the temperature coefficient of resistance may be obtained.

Alternatively, one may obtain α/κ from a differential, that is to say dual set of measurements, subtracted from one another. For two symmetric pin configurations A and A′, the first harmonic resistances at zero heating are equal:

R_{A,0}R_{A′,0}.

while the increase of resistance with current is different:

$$\frac{{R}_{A}}{{R}_{A , 0}} = 1 + \frac{α}{κ} {M}_{A} {I}^{2} , \\ \frac{{R}_{A ′}}{{R}_{A ′ , 0}} = 1 + \frac{α}{κ} {M}_{A ′} {I}^{2}$$

Subtracting the first harmonic resistances of these two configurations from one another yields:

$$\frac{{R}_{A} - {R}_{A ′}}{{R}_{A , 0}} = \frac{α}{κ} ( {M}_{A} - {M}_{A ′} ) {I}^{2}$$

Given that (R_{A}−R_{A′})<<R_{A,0}, the above may be approximated as y=(R_{A}−R_{A′})/R_{A}, and x=(M_{A}−M_{A′})I², whose linear slope corresponds to α/κ as before, however only dependent on first harmonic resistances.

As exemplified above, the extraction of α/κ is possible from various combinations of first and third harmonic resistance, in either single or multiple configuration settings, enabling to cross-validate the internal consistency of the data and remove potential systematic errors or second-order effects.

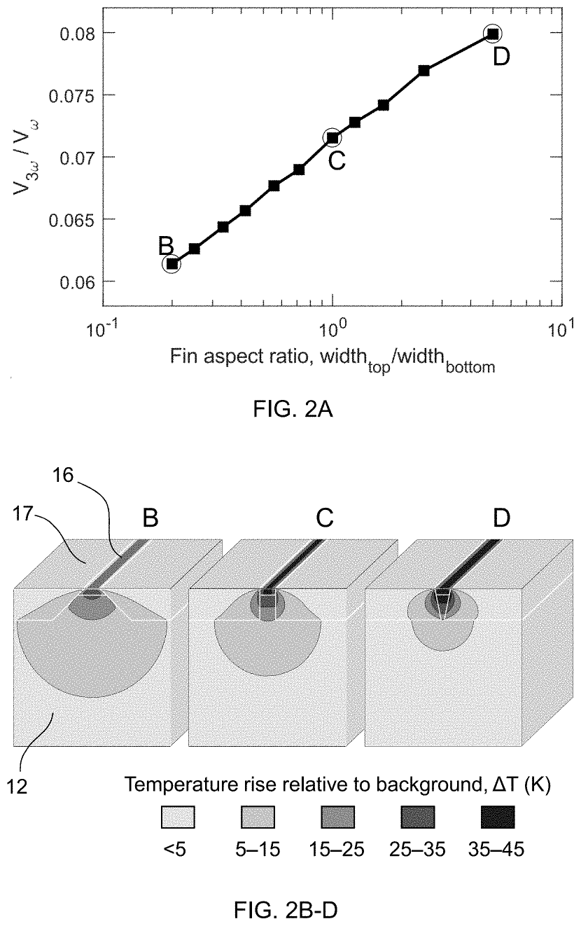

FIGS. 2B-D illustrates three different profiles of a fin 16 having three different fin aspects ratios.

In FIG. 2B illustrates a fin having a wider base than top, i.e. with a fin aspect ratio greater than one.

In FIG. 2C illustrates a fin having perfectly vertical sidewalls, i.e. same width at the top as at the base so that the fin aspect ratio is one.

In FIG. 2D illustrates a fin having a narrower base than top, i.e. with a fin aspect ratio smaller than one.

In each of FIGS. 2B-D it is illustrated that the fin is heated to a temperature higher than background temperature, for example by applying an electrical current traversing the fin.

Heat transfer in the test sample means that the heat in the fin will spatially distribute in the test sample. How the heat will be distributed and how the temperature gradient will evolve is illustrated by the different shades of grey separated by isotherm lines (darkest fill color illustrates the highest temperature at the fin where the current runs and lightest fill color illustrates the lowest temperature progressively away from the fin.)

The heat flow both within the fin as well as away from the fin into the rest of the test sample depends among other things on the shape and geometry of the fin. In other words, the thermal resistance, or how temperature evolves inside and outside of the fin, strongly depends on the shape and geometry of the fin. It is seen that for the fin in FIG. 2B having a fin aspect ratio greater than one, heat is dissipated farther away from the fin than compared to the two other shapes of fins illustrated in FIGS. 2C and 2D respectively. High temperature is most localized in fins with high aspect ratios, e.g. the fin depicted in FIG. 2D, and is least localized in fins with low aspect ratios, e.g. the fin depicted in FIG. 1B.

It is assumed that the substrate 12 is the same in all of FIGS. 2B-D, and that the top of the fin 16 and the electrically insulating oxide 17 are also the same for all points simulated in FIG. 2A, and in all of FIGS. 2B-D. The electrical currents are also identical across all the simulated fins. Only the aspect ratio of the fin is varied in FIG. 2, and the resulting harmonic components of the measured voltage are numerically simulated and extracted. It is important to note, that changing the substrate and/or oxide can affect the heat transfer. For example, a substrate with a higher thermal conductivity will conduct more heat away from the fin, if all other material properties and geometries remain unchanged.

The change of resistance with temperature may be used to characterize the fin. In other words, the variation of the fins' ability to conduct and redistribute heat (variation that arises from the fins' geometry and shape), may be used to directly quantify a certain geometrical property of the fin (e.g. its aspect ratio), or indirectly infer whether or not the fin meets a certain required specification (e.g. aspect ratio above or below a required threshold).

A target may be defined for the test sample (the respective property of the test sample), for example the fin aspect ratio as in FIG. 2. A threshold may be defined as a set of certain experimental values or their ratios (e.g. voltage amplitudes), or a percentage from a desired ratio, or a percentage of a desired geometric property, beyond which the test sample would be rejected. Otherwise the sample would be accepted. For example, if a threshold is 20% and the target fin aspect ratio is 1, the test sample is accepted if the measured fin aspect ratio is between 0.8 and 1.2.

The threshold may depend on the property to be measured or the target, i.e. if the specification has a large manufacturing tolerance, the threshold may be high, and if the tolerance is low, the threshold may be low.

The threshold may also depend on the measurement uncertainty.

For example, if the target is a fin aspect ratio of 1, the threshold may be defined to be 20%, but if the target is a fin aspect ratio of 1.2, the threshold may be defined to be 30%.

It may also be so that if there are two properties close to each other, for example test samples with desired aspect ratios of 1, and test samples with desired aspect ratios of 1.1, the threshold is not to be bigger than the difference between the two targets, i.e. for example not more than a threshold of 10%.

The test sample may be heated by applying a current through an arbitrary pair of electrodes. The temperature increase may depend on either current amplitude, or frequency, or both. Typically, a current amplitude is chosen such that the increase in temperature would be measurable, i.e. the current should not be too small such as the electric noise in general would be greater than the voltage to be measured due to the temperature increase.

Naturally, the current should also not be too large to impose detrimental or irreversible effects upon the test sample.

The measurement of the voltage could then take place at a point in time after the current is applied, so that the test sample has had time to reach a thermal equilibrium, i.e.

thermal steady state. The time delay between current switching and voltage measurement may depend on the current, the shape and dimension of the test material, and its physical properties such as thermal conductivity and/or resistivity.

The measurement may take place by applying an alternating current I₀sin(ωt) across the first pair of electrodes having a smaller amplitude than the current used for heating, and measuring the voltage across the second electrode pair, while current is applied across the first electrode pair.

The temperature dependence of the resistivity will depend on the amplitude/value at the third harmonic frequency. Thus, for the third harmonic frequency, the measured voltage will have the proportionality relationship V_{3ω}˜sin(3ωt).

The value at the third harmonic which is proportional to the amount of heating may be found by filtering the measured voltage or by studying the frequency domain, i.e. by decomposing the measured voltage into a continuum of underlying frequencies that sum up to the observed signal.

A set of reference values may be determined in order to correlate a measured voltage to a specific sample property, i.e. a reference set may be defined comprising a number of pairs of voltage V and property P, i.e. (V, P). Such a reference set may be calibrated on known materials to establish a functional relationship (either empirical or theoretical) between the observed voltage and the sample property of interest V=f(P), and then utilized in a reverse sense on unknown samples, to obtain sample properties from the observed voltage P=f⁻¹(V). Note that since V can be recorded at multiple frequencies, composite reference sets, e.g. pairs of (V_{3ω}/V₁₀₇ , P), or multivariate reference sets, e.g. triplets of (V₁₀₇ , V_{3ω}, P), or the like, can likewise be constructed and used as interpolation (look-up) tables for specific sample properties of interest.

For example, assuming a set of test samples having fins with known fin aspect ratios, which have been determined e.g. optically by use of a microscope. A current (preferably of the same value in each measurement) is injected into each known fin, and the voltage may be measured such that for each specific fin aspect ratio, the associated voltage is known. This is how the numerically-simulated relationship in FIG. 2A could be determined experimentally.

For a test sample comprising of a fin with an unknown aspect ratio, its aspect ratio may be determined by comparing the measured voltage due to an applied current to a set of reference values, i.e. to determine whether the measured voltage is comparable to one of the voltages in the set of reference values (i.e. in particular, the amplitudes and phases of the first and third harmonic frequencies of the voltage). If it is, it may be inferred that the unknown fin has a fin aspect ratio comparable to that of the reference measurement.

FIG. 2A shows a graph where the measured voltage is related to fin aspect ratio.

15

The voltage metric is shown along the y-axis. Specifically, the graph shows the amplitude of the third harmonic frequency (3ω), V_{3ω}sin(3ω), normalized/scaled by the amplitude of the fundamental (ω), V_{W} sin(ω), i.e. the ratio of the third over the first harmonic voltage V_{3 7}/V_{ω.}

In the plot, the fin aspect ratio shown along the x-axis increases with voltage, going from a fin aspect ratio of ⅕ for the leftmost point on the curve to a value of 5 for the rightmost point on the curve.

The fin from FIG. 2B is illustrated as the filled square next to the “B”. For this fin a ratio of the third over the first harmonic voltage of 0.061 is measured.

The fin from FIGS. 2C and 2D are also illustrated, and for these fins the measured ratios of third to first harmonic voltages are around 0.072 and 0.080 respectively.

FIG. 2A may constitute a set of reference values.

For example, a test sample having a fin with an unknown fin aspect ratio is measured having a third over first harmonic voltage ratio of 0.07. It may then be inferred that it is likely that the unknown fin has an aspect ratio of around one.

Alternatively, it may be desired that the test sample is to have a fin with a fin aspect ratio of one within a threshold/margin of 20%. A voltage of 0.075 is measured. However, this corresponds to a fin aspect ratio of 2, which is outside the set threshold/margin. The test sample does therefore not meet the desired specification.

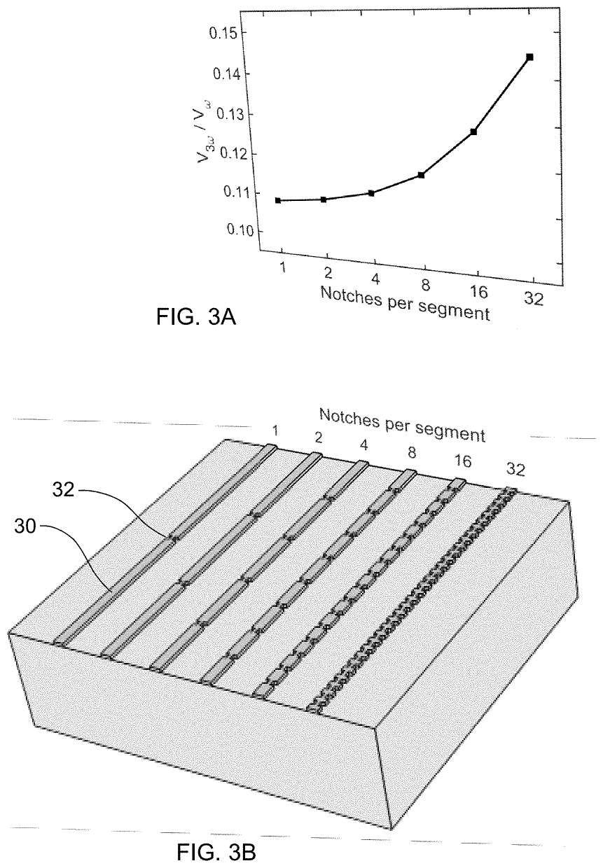

FIG. 3B is an example of another property of a test sample that may be measured thermoelectrically.

FIG. 3B shows six examples of different electric lines in a test sample. The first line 30 has a single notch 32 (indentation) along its length, i.e. the line exhibits a narrow passage at its center. The line next to it has two notches. The third line has four notches. The fourth, fifth and sixth lines has 8, 16 and 32 notches, respectively. All notches are distributed equidistantly from one another, and exemplify otherwise similar lines with varying degrees of edge roughness.

FIG. 3A shows the effect of the six different shapes/geometries on the measured voltage when an electric current is conducted along the line. Specifically, it can be seen in FIG. 3A that the scaled third harmonic voltage increases in proportionality with the number of notches.

In a similar manner to how the measured voltage parameters were indicative of the fin aspect ratio (in cross section perpendicular to the current flow) in FIG. 2A, the measured voltage parameters in FIG. 3A show a set of reference values for the line shape (where the geometric property that can be monitored is along the current flow).

The set of reference values may be determined from measuring voltage on lines with known geometries, specifically by measuring the voltage between a pair of probe electrodes while applying a current along the line via another pair of probe electrodes, and defining pairs of voltage and notch numbers/densities (V_{3ω}/V₁₀₇ , P).

The set of reference values comprising pairs of voltage harmonic ratios and notch density may be used to either determine whether a test sample consisting of a conducting line meets a certain specification, or to infer how many notches there likely are in a line.

For example, for an unknown test sample, a third to first harmonic voltage ratio of 0.11 is measured. Comparing to the set of reference values, it is seen that a third to first harmonic voltage ratio of 0.11 corresponds to a line having a single notch.

Similarly, it may be the manufacturing specification that a test sample should have a line with sixteen notches within a tolerance/threshold of for example 10%. If during measurement of a test sample, the observed voltage is 0.129 (which is within 10% of the reference with sixteen samples having a voltage of 0.13), it can be inferred that such a particular test sample is accepted, i.e. it is inferred that the measured line on the test sample is likely to have 16 notches.

In this way, a thermal electric property may be determined just by landing a four point probe once on the sample and do one test instead of having to land for example a multitude of times or do a multitude of current injections before a new test sample can be tested. This reduces the influence of the measurement/test on the test sample, and is more efficient, enabling e.g. a large number of measurements to be made.

The heat dissipated in the fin and/or other part(s) of the test sample being measured causes an increase in resistance. Measuring the resistance at room temperature may therefore lead to a larger resistance value than what the resistance at room temperature is, due to the injected current. Thus, the experimental resistance R=V/I, obtained from dividing the measured voltage V by the applied current I may contain a significant offset from the ideal resistance R₀ at room temperature. The magnitude of this offset, arising from localized heating of the material by the applied electric current, depends on the current amplitude, frequency and shape of the material under test. The said offset may be reduced for example by adding the amplitude of the third harmonic to the measured first harmonic voltage, i.e.

$${R}_{0} \approx \frac{V + 3 {V}_{3 ω}}{I}$$

or potentially some otner scaling of the amplitude of the third harmonic.

Now, follows a set of points which constitute aspects of the present invention which may be considered independently patentable and as such the following set form basis for possible future sets of claims.

What is claimed is:

1. A method for measuring a property in response to a temperature modulation of a test sample, said method comprising:
providing said test sample, said test sample being made of an electrically conducting or semiconducting material,
providing at least two terminals and at least two electrically conducting interconnections between said at least two terminals and said electrically conducting or semiconducting material, said at least two electrically conducting interconnections contacting at least two positions at said electrically conducting or semiconducting material,
providing a power source and an electric circuit for generating a current and injecting said current into said electrically conducting or semiconducting material by means of said terminals,
measuring the voltage across a part of said electrically conducting or semiconducting material by means of said terminals, and
determining said property as a function of the value of the third harmonic frequency component of said measured voltage.

2. The method according to claim 1, wherein said current has an amplitude for heating said test sample to a temperature above a background temperature.

3. The method according to claim 1, further comprising determining said property as a function of the value of the fundamental frequency component of said measured voltage.

4. The method according to claim 1, further comprising comparing the measured voltage to a set of reference values for screening the shape or determining the shape of an electrical component or interconnection.

5. The method according to claim 4, wherein said set of reference values comprises coordinates or pairs relating shapes of an electrically conducting layer or electrically conducting line as a function of voltage resulting from heating.

6. The method according to claim 4, wherein said set of reference values comprises coordinates or pairs relating shapes of an electrically conducting layer or electrically conducting line as a function of voltage at the third harmonic frequency resulting from heating.

7. The method according to claim 4, further comprising defining a threshold for accepting or rejecting said test sample.

8. The method according to claim 7, further comprising defining a target reference value in said set of reference values for accepting or rejecting said test sample.

9. The method according to claim 8, further comprising rejecting said test sample when a difference between said voltage and said target is greater than said threshold.

10. The method according to claim 8, further comprising accepting said test sample when a difference between said voltage and said target is smaller than said threshold.

11. The method according to claim 4, comprising comparing said measured voltage to said set of reference values.

12. The method of claim 1, wherein the electrically conducting or semiconducting material is an electrically conducting layer, an electrically conducting line, or a magnetic tunnel junction.

13. The method of claim 1, wherein the at least two terminals includes four terminals.

14. A method for determining the temperature coefficient of resistance, said method comprising:
providing said test sample, said test sample being made of an electrically conducting or semiconducting material,
providing a set of terminals including at least four terminals and at least four electrically conducting interconnections between said terminals and said electrically conducting or semiconducting material, said four electrically conducting interconnections contacting four positions at said electrically conducting or semiconducting material,
providing a power source and an electric circuit for generating a current, injecting a first current into said test sample by means of a first combination of two terminals from said set of terminals,
measuring a first voltage by means of a second combination of two terminals from said set of terminals,
injecting a second current into said test sample by means of a third combination of two terminals from said set of terminals,
measuring a second voltage by means of a fourth combination of two terminals from said set of terminals, and
determining the temperature coefficient of resistance or a value proportional to the temperature coefficient of resistance as a function of said first current, said second current, said first voltage, and said second voltage.

15. The method of claim 14, wherein the electrically conducting or semiconducting material is an electrically conducting layer, an electrically conducting line, or a magnetic tunnel junction.

16. A method for determining an electric property of a test sample, said method comprising:
providing said test sample, said test sample being made of an electrically conducting or semiconducting material,
providing at least two terminals and at least two electrically conducting interconnections between said two terminal and said electrically conducting or semiconducting material, said two electrically conducting interconnections contacting two positions at said electrically conducting or semiconducting material, providing a power source and an electric circuit for generating a current and injecting said current into said electrically conducting or semiconducting material by means of said terminals,
measuring the voltage across a part of said electrically conducting or semiconducting material by means of said terminals, and
determining an electric resistance of said electrically conducting or semiconducting material at a reference temperature as a function of said injected current, said measured voltage, and a value of a third harmonic frequency component of said measured voltage.

17. The method of claim 16, wherein the electrically conducting or semiconducting material is an electrically conducting layer, an electrically conducting line, or a magnetic tunnel junction.

18. The method of claim 16, wherein the at least two terminals includes four terminals.
